(19) United States
(12) Patent Application Publication
(10) Pub. No.: US 2015/0110224 A1
(43) Pub. Date: Apr. 23, 2015

(54) INTERFACE DEVICE FOR PERFORMING ON-OFF KEYING MODULATION AND TRANSMITTER USING SAME

(71) Applicant: ELECTRONICS AND TELECOMMUNICATIONS RESEARCH INSTITUTE, Daejeon-city (KR)

(72) Inventors: Taeyoung KANG, Seoul (KR); Byounggun CHOI, Daejeon (KR); Kyunghwan PARK, Daejeon (KR)

(73) Assignee: ELECTRONICS AND TELECOMMUNICATIONS RESEARCH INSTITUTE, Daejeon-city (KR)

(21) Appl. No.: 14/516,095

(22) Filed: Oct. 16, 2014

(30) Foreign Application Priority Data
Oct. 17, 2013 (KR) 10-2013-0123700

(51) Int. Cl. H04L 27/00; H03H 11/22; H03H 11/18; H04L 27/04; H03K 19/0185

(52) U.S. Cl. CPC H04L 27/0008; H04L 27/04; H03K 19/018521; H03H 11/18; H03H 11/22
USPC 375/300; 327/257

(57) ABSTRACT

An interface device for performing on-off keying (OOK) modulation and a transmitter using the interface are disclosed. The interface device includes a first inverter and a second inverter. The first inverter outputs a signal to a first output terminal based on a digital baseband signal when the digital baseband signal is applied thereto. The second inverter outputs a signal to a second output terminal based on a signal obtained by inverting the phase of the digital baseband signal when the digital baseband signal is applied thereto.

### CROSS-REFERENCE TO RELATED APPLICATION

This application claims the benefit of Korean Patent Application No. 10-2013-0123700, filed Oct. 17, 2013, which is hereby incorporated by reference herein in its entirety.

### BACKGROUND OF THE INVENTION

1. Technical Field

The present disclosure relates to an interface device for performing on-off keying (OOK) modulation and a transmitter using the interface.

2. Description of the Related Art

With the development of digital image media technology and an increase in demand for fast wireless transmission, attempts to implement tens of Gbps-level wireless transmission have been made chiefly by technologically advanced countries. These attempts have been accelerated through various standardization activities. As results of these attempts, the standards “IEEE 802.15.3c,” “ECMA-387” and “Wireless HD” in the 60 GHz mm waveband have been established, and IEEE 802.12.ad is currently being standardized. These standards adopt phase-shift keying (PSK) and quadrature amplitude modulation (QAM) as their modulation methods, whereas ECMA-387 stipulates that an OOK modulation method must be compulsorily used.

PSK is a modulation technique that is widely used for digital data communication for many low-frequency radio frequency (RF) applications. In the simplest form, a transmitter sends a high-amplitude carrier when desiring to send “1,” and sends a low-amplitude carrier when desiring to send “0.” OOK is a method obtained by simplifying the former method, and is configured in such a way that a transmitter does not send a carrier by turning on/off a power amplifier or a voltage-controlled oscillator (VCO) when desiring to send “0.” OOK is chiefly used for a simple portable device because transmission power can be reduced, particularly when a transmitter sends “0.”

It is difficult to perform ON and OFF operations at tens of GHz by blocking the operating current of the power amplifier or VCO of a transmitter to send tens of Gbps-level data in the 60 Ghz mm waveband using an OOK method. A method of transmitting an OOK modulation signal by selectively sending a 60 GHz sine wave, that is, the output of a VCO, to a power amplifier and blocking it in such a way that an OOK baseband signal operates a switch using the switch with respect to the generally used power amplifier input is also disadvantageous in that it increases an undesirable parasitic component in the 60 GHz signal pass and in that a 60 GHz RF circuit becomes complicated when it is used along with another modulation method.

Korean Patent Application Publication No. 10-2012-0038275 proposes an OOK modulation device in which a switch has been combined with an amplifier. Although this OOK modulation device has the advantage of providing OOK modulation in the millimeter waveband using low power, the OOK modulation device is disadvantageous in that it is difficult for a tens of GHz OOK baseband signal to switch the gate bias of a transistor and in that also it is difficult to use the OOK modulation device in cooperation with another modulation method using 60 GHz mm-waves as a carrier. Furthermore, a technology for supporting dual mode, including OOK and FSK modes, was proposed. This technology is disadvantageous in that it can be used only for low frequency control but is not suitable for fast data transmission.

### SUMMARY OF THE INVENTION

Accordingly, at least one embodiment of the present invention is directed to an OOK modulation interface device having a simple structure, which enables a fast OOK modulation method to be additionally provided in a transmitter using a PSK or QAM modulation method, and a transmitter using the interface device.

In accordance with an aspect of the present invention, there is provided an interface device, including a first inverter configured to, when a digital baseband signal is applied thereto, output a signal to a first output terminal based on the digital baseband signal; and a second inverter configured to, when the digital baseband signal is applied thereto, output a signal to a second output terminal based on a signal obtained by inverting the phase of the digital baseband signal.

Each of the first and second inverters may include a pair of transistors, and may turn on any one of the pair of transistors in response to the level of an applied signal and then output a signal.

The pair of transistors of each of the first and second inverters may be a p-channel metal-oxide-semiconductor (PMOS) transistor and a n-channel metal-oxide-semiconductor (NMOS) transistor; and the drain and source of the NMOS transistor of the first inverter may be connected to the source and drain of the PMOS transistor of the second inverter, respectively.

The interface device may further include an inverter configured to invert a phase of the applied digital baseband signal by 180 degrees and to output the inverted signal.

The interface device may further include a device connected to an input terminal and configured to eliminate a direct current (DC) component from the digital baseband signal input to the input terminal.

The device configured to eliminate the DC component may be a capacitor.

The first and second inverters, when the digital baseband signal is “0,” may output signals having a value of VDD and a value of VSS, respectively, and, when the digital baseband signal is “1,” may output signals having identical values.

In accordance with another aspect of the present invention, there is provided a transmitter, including a first signal processing unit configured to, when a first digital baseband signal is input, output a first signal based on the first digital baseband signal, and output a second signal based on a signal obtained by inverting a phase of the first digital baseband signal; a second signal processing unit configured to, when a second digital baseband signal is input, convert the second digital baseband signal into an analog signal, eliminate a high frequency component from the analog signal, and output a signal free of the high frequency component; and a frequency mixing unit configured to modulate and output an output signal of the first or second signal processing unit.

The first signal processing unit, when the digital baseband signal is “0,” may output the first and second signals having different values, and, when the digital baseband signal is “1,” may output the first and second signals having identical values.

The first digital baseband signal may be a digital baseband signal for on-off keying (OOK) modulation.

The second digital baseband signal may be a digital baseband signal for phase-shift keying (PSK) modulation or quadrature amplitude modulation (QAM).

The transmitter may further include a power amplification unit configured to amplify an output signal of the frequency mixing unit; and an antenna configured to propagate the amplified output signal.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram of a transmitter according to an embodiment of the present invention;

FIG. 2 illustrates an example of an input signal of the first signal processing unit of the transmitter of FIG. 1;

FIG. 3 illustrates an example of an output signal of a frequency mixing unit with respect to the input signal of FIG. 2;

FIG. 4 is a circuit diagram of an interface device according to an embodiment of the present invention;

FIG. 5 illustrates an example of a signal input to the first inverter of the interface device of FIG. 4;

FIG. 6 illustrates an example of a signal input to the second inverter of the interface device of FIG. 4;

FIG. 7 illustrates an example of an output signal of the first and second inverters of the interface device of FIG. 4; and

FIG. 8 is an example of a circuit configured to select DC biases.

### DESCRIPTION OF THE PREFERRED EMBODIMENTS

Reference now should be made to the drawings, throughout which the same reference numerals are used to designate the same or similar components.

Interface devices for performing OOK modulation and transmitters using the interface devices according to embodiments of the present invention are described with reference to the accompanying drawings.

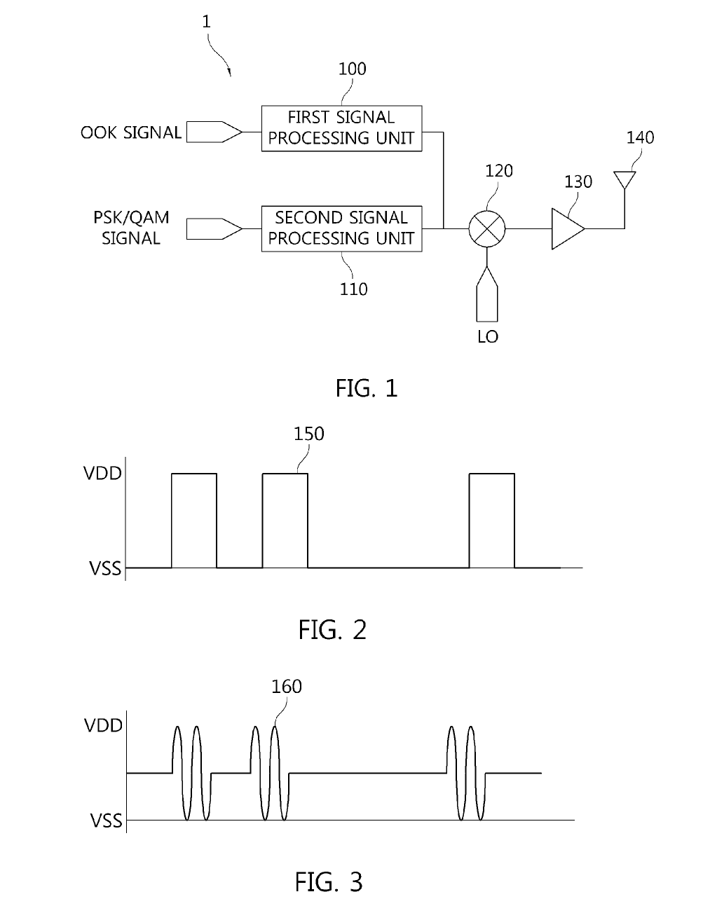

FIG. 1 is a diagram of a transmitter according to an embodiment of the present invention. FIG. 2 illustrates an example of an input signal of the first signal processing unit of the transmitter of FIG. 1. FIG. 3 illustrates an example of an output signal of a frequency mixing unit with respect to the input signal of FIG. 2.

Referring to FIG. 1, a transmitter 1 may include a first signal processing unit 100, a second signal processing unit 110, a frequency mixing unit 120, a power amplification unit 130, and an antenna 140.

In accordance with an embodiment of the present invention, when a first digital baseband signal 150, such as that illustrated in FIG. 2, is input to an input terminal, the first signal processing unit 100 may output a signal suitable for the modulation processing of the frequency mixing unit 120 based on the input signal.

In this case, the first digital baseband signal 150 may be a digital baseband signal for OOK modulation, which is used for the frequency mixing unit 120 to perform OOK processing.

Furthermore, the first signal processing unit 100 may be an OOK interface circuit that processes a digital baseband signal for OOK modulation in order to directly apply the processed signal to the frequency mixing unit 120 of the transmitter 1.

When the first digital baseband signal 150 is input, the first signal processing unit 100 may output a first signal based on the first digital baseband signal 150, and a second signal based on an inverted signal generated by inverting the phase of the first digital baseband signal 150.

The input first digital baseband signal 150 may be applied to the frequency mixing unit 120 immediately after passing through the first signal processing unit 100 without the intervention of a separate digital to analog converter (DAC) that converts a digital signal into an analog signal.

In this case, when the input first digital baseband signal 150 input to the input terminal is “0,” the first signal processing unit 100 may output the first and second signals so that they have different values, and thus they are not processed by the frequency mixing unit 120.

Furthermore, when the first digital baseband signal 150 is “1,” the first and second signals may be output such that they have the same value, and be then modulated by the frequency mixing unit 120. That is, when the first digital baseband signal 150 is “1,” the first and second signals may be output such that they have the same value as the input bias voltage of the frequency mixing unit 120.

The second signal processing unit 110 may include a digital-analog converter and a baseband filter, which are not illustrated. When a second digital baseband signal is input to the input terminal, the second digital baseband signal is converted into an analog signal while passing through the digital-analog converter, and the analog signal obtained by converting the second digital baseband signal is deprived of a high frequency component while passing through the baseband filter.

In this case, the second digital baseband signal may be a digital baseband signal for PSK or QAM modulation.

Furthermore, the second signal processing unit 110 may be an analog baseband circuit that processes a digital baseband signal for PSK or QAM modulation in order to apply the processed signal to the frequency mixing unit 120 of the transmitter 1.

The frequency mixing unit 120 may be, for example, a frequency mixer, and modulates and outputs a signal output from the first or second signal processing unit 100 or 110.

The frequency mixing unit 120 outputs a VCO signal when the first digital baseband signal 150 is “1,” as illustrated in FIG. 3. In contrast, the frequency mixing unit 120 does not output a signal when the first digital baseband signal 150 is “0.”

The power amplification unit 130 may be, for example, a power amplifier, and may amplify a signal output from the frequency mixing unit 120 based on the output condition of the transmitter 1.

Meanwhile, since a 60 GHz signal has a strong rectilinear property and can be easily absorbed by air, both the power amplifier 130 and a phase shifter (not illustrated) may form an array.

The antenna 140 propagates the signal amplified by the power amplification unit 130.

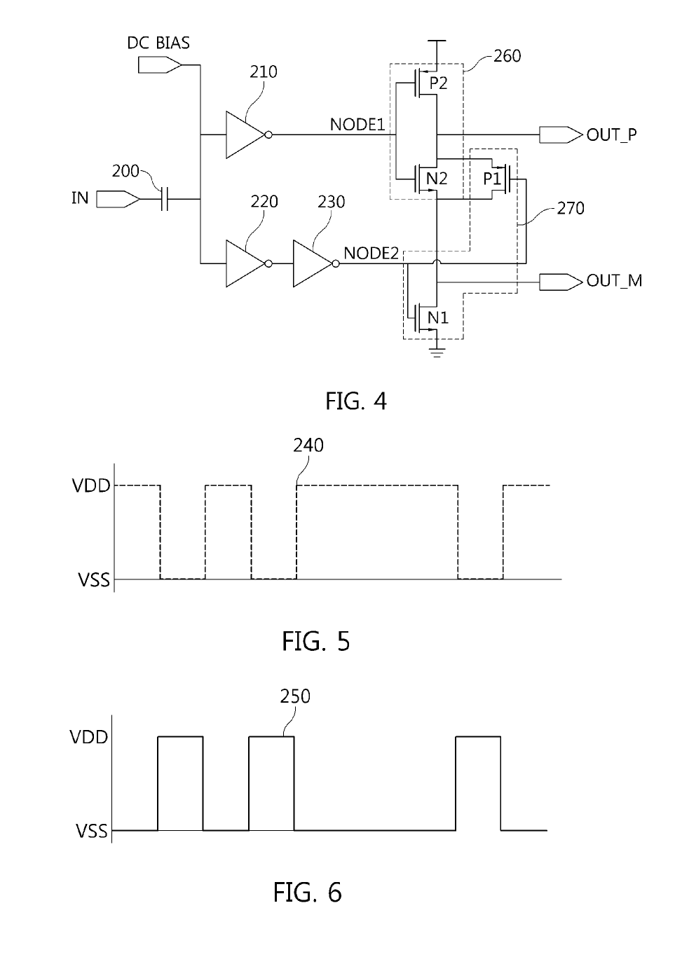

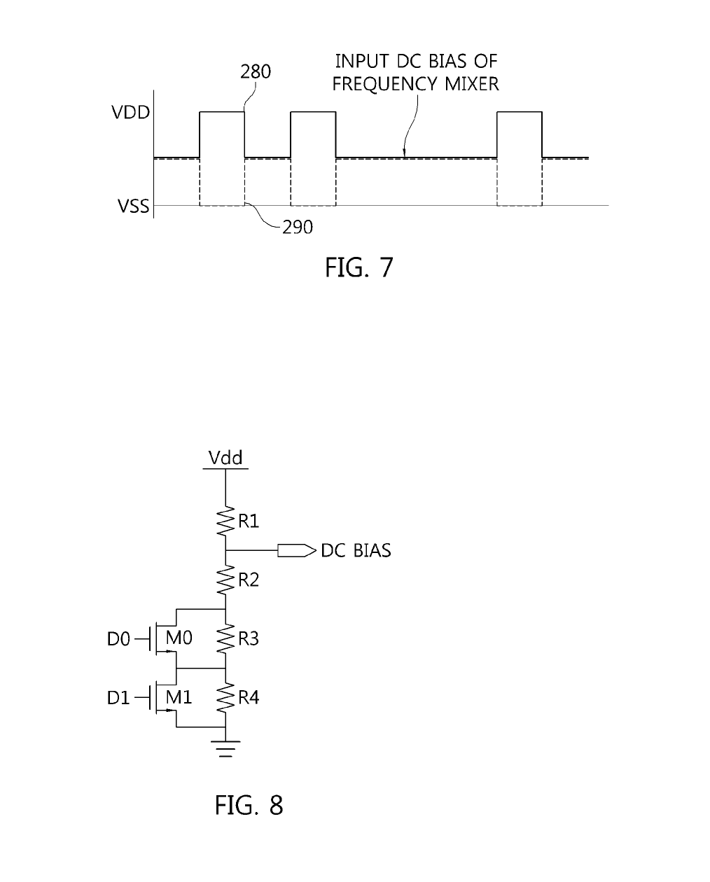

FIG. 4 is a circuit diagram of an interface device according to an embodiment of the present invention. FIG. 5 illustrates an example of a signal input to the first inverter of the interface device of FIG. 4. FIG. 6 illustrates an example of a signal input to the second inverter of the interface device of FIG. 4. FIG. 7 illustrates an example of an output signal of the first and second inverters of the interface device of FIG. 4.

The interface device illustrated in FIG. 4 may be a device that constitutes the first signal processing unit 100 that processes OOK modulation in the transmitter 1 of the embodiment of FIG. 1.

Referring to FIG. 4, the interface device may include a plus path in which a digital baseband signal input to an input terminal IN to provide a differential input to the frequency mixer passes through an upper circuit part and is output via an output terminal OUT_P as a single signal, and a minus path in which another signal passes through a lower circuit part and is then output via an output terminal OUT_M.

The interface device may include a first inverter 260 on the plus path and a second inverter 270 on the minus path.

When a digital baseband signal is applied to the input terminal IN, the first inverter 260 outputs a single signal via the first output terminal OUT_P based on the digital baseband signal.

Furthermore, when a digital baseband signal is applied to the input terminal IN, the second inverter 270 outputs a signal via the second output terminal OUT_M based on a signal generated by inverting the phase of the digital baseband signal.

Meanwhile, the interface device may include a device 200 that is connected to the input terminal IN and eliminates a DC component from an input digital baseband signal. In this case, the device 200 configured to eliminate a DC component may be a capacitor.

A DC bias is applied to the input of the inverters to which DC component-free signals are applied. Although half of a power source voltage, that is, VDD/2, is used as a bias, it is difficult to know the values of outputs because of a change in process or an operating environment when the input bias of the inverters is VDD/2.

The interface device may include a circuit capable of selecting various DC biases via digital input, as illustrated in FIG. 8.

FIG. 8 is an example of a circuit configured to select DC biases.

An example of selecting a DC bias is described with reference to FIG. 8. Although two bits [D1:D0] are described as being selected by way of example for ease of description, actually it may be possible to perform minute control using a larger number of bits.

When [D1:D0]=“0,” the DC bias is Vdd*(R1/(R1+R2+R3+R4)). When D0 or D1 is the logic “1,” M0 or M1 is turned on, and thus R3 or R4 becomes 0. In this case, assuming that R3=R4 and R1=R2+R3, the DC bias is lower than Vdd/2 when [D1:D0]=“00,” the DC bias is equal to Vdd/2 when [D1:D0]=“01” or [D1:D0]=“10,” and the DC bias is higher than Vdd/2 when [D1:D0]=“11.”

The DC bias that is determined through digital control may be determined to be a value closest to Vdd/2 as, when the input is the logic “00,” the first output terminal OUT_P and the second output terminal OUT_M come to have the same value, as illustrated in the first state of FIG. 7.

A digital baseband signal that has been deprived of a DC component while passing through the DC elimination device 200 is applied to the first inverter 260 of the plus path and the second inverter 270 of the minus path.

Meanwhile, the interface device may include inverters 210 and 220 connected to the DC elimination device 200 on the plus path and the minus path, respectively. FIG. 4 illustrates an example including the inverters 210 and 220. If there are no inverters 210 and 220, the locations of the first output terminal OUT_P and the second output terminal OUT_M are switched.

The inverter 210 on the plus path may be connected in series to the first inverter 260. The digital baseband signal having passed through the DC elimination device 200 is output as a first node signal 240 through the inverter 210, as illustrated in FIG. 5, and the output first node signal 240 is applied to the first inverter 260.

Furthermore, the inverter 220 on the minus path inverts the digital baseband signal having passed through the DC elimination device 200, and outputs a node signal to be applied to the second inverter 260.

In this case, the interface device may further include an inverter 230, connected in series to the inverter 220 and the second inverter 270, on the minus path.

The inverter 230 may invert the phase of the node signal output from the inverter 220 connected to the DC elimination device 200 by 180 degrees, and may output a second node signal 250, such as that illustrated in FIG. 6.

Referring to FIG. 4 again, the first inverter 260 may include a pair of transistors P2 and N2. In this case, the pair of transistors P2 and N2 may be a PMOS transistor P2 and an NMOS transistor N2.

In the same manner, as illustrated in FIG. 4, the second inverter 270 may also include a pair of transistors P1 and N1, and the pair of transistors P1 and N1 may be a PMOS transistor P1 and an NMOS transistor N1.

Furthermore, as illustrated in FIG. 4, the drain and source of the NMOS transistor N2 of the first inverter 260 may be connected to the source and drain of the PMOS transistor P1 of the second inverter 270, respectively, and the source of the NMOS transistor N1 of the second inverter 270 may be grounded.

In this case, the NMOS transistor N2 of the first inverter 260 that outputs a signal using the first node signal 240 as input and the PMOS transistor P1 of the second inverter 270 that outputs a signal using the second node signal 250 as input may operate as a transmission gate.

Meanwhile, the inverter 210 on the plus path is connected to the gates of the transistors P2 and N2 of the first inverter 260, and thus the first node signal 240 output from the inverter 210 is applied to the gates of the transistors P2 and N2 of the first inverter 260.

In the same manner, the inverter 230 on the minus path is connected to the gates of the transistors P1 and N1 of the second inverter 270, and the second node signal 250, whose phase has been inverted by 180 degrees by the inverter 230 and output from the inverter 230, is applied to the gates of the transistors P1 and N1 of the second inverter 270.

The transistors P2 and N2 of the first inverter 260 performs a turn-on or turn-off operation in response to the level of the applied first node signal 240, and a signal output via any one turned-on transistor is output via the first output terminal OUT_P.

The transistors P1 and N1 of the second inverter 270 performs an turn-on or turn-off operation in response to the level of the applied second node signal 250, and a signal output via any one turned-on transistor is output via the second output terminal OUTM.

For example, when the level of the applied first node signal 240 is low and the level of the second node signal 250, which is an inverted signal, the NMOS transistor N1 of the first inverter 260 is turned off and the PMOS transistor P2 thereof is turned on. In this case, the NMOS transistor N2 of the second inverter 270 is turned on, and the PMOS transistor P2 thereof is turned off.

In this case, as illustrated in FIG. 7, the turned-on transistor P2 of the first inverter 260 outputs a signal 280 to the first output terminal OUT_P so that the signal has a value of VDD, and the turned-on transistor N1 of the second inverter 270 outputs a signal 290 to the second output terminal OUT_M so that the signal 290 has a value of VSS. That is, in this case, it may be possible to reduce the correlation between two outputs by allowing high impedance to be established between the outputs of the first output terminal OUT_P and the second output terminal OUT_M.

In contrast, when the level of the applied first node signal 240 is high and the level of the second node signal 250 is low, the NMOS transistor N2 of the first inverter 260 is turned on and the PMOS transistor P2 thereof is turned off. In this case, the NMOS transistor N1 of the second inverter 270 is turned off, and the PMOS transistor P1 thereof is turned on.

In this case, as illustrated in FIG. 7, the turned-on transistor P2 of the first inverter 260 and the turned-on transistor N1 of the second inverter 270 output two output signals to allow them to have the same value so that low impedance is established between the output signal 280 of the first output terminal OUT_P and the output signal 290 of the second output terminal OUT_M.

When the output signal 280 of the first output terminal OUT_P and the output signal of the second output terminal OUT_M have the same value, as described above, the output signals have the same value as the bias voltage of the input frequency mixer.

In accordance with the disclosed embodiment, a digital baseband signal for OOK modulation having passed through the interface device can be directly input to the frequency mixer of the transmitter, and thus it is easy to add the interface device for performing OOK modulation to a general PSK/QAM transmitter.

In accordance with at least one embodiment of the present invention, a fast OOK modulation method can be provided in addition to a PSK/QAM modulation in a transmitter using a PSK/QAM modulation method by using an interface circuit having a structure. Furthermore, a circuit can be added without influence on radio frequency (RF) characteristics by using an OOK interface circuit for the input of a frequency mixer.

Although the preferred embodiments of the present invention have been disclosed for illustrative purposes, those skilled in the art will appreciate that various modifications, additions and substitutions are possible without departing from the scope and spirit of the invention as disclosed in the accompanying claims.

What is claimed is:

1. An interface device, comprising:
a first inverter configured to, when a digital baseband signal is applied thereto, output a signal to a first output terminal based on the digital baseband signal; and
a second inverter configured to, when the digital baseband signal is applied thereto, output a signal to a second output terminal based on a signal obtained by inverting a phase of the digital baseband signal.

2. The interface device of claim 1, wherein each of the first and second inverters comprises a pair of transistors, and turns on any one of the pair of transistors in response to a level of an applied signal and then outputs a signal.

3. The interface device of claim 2, wherein:
the pair of transistors of each of the first and second inverters are a p-channel metal-oxide-semiconductor (PMOS) transistor and a n-channel metal-oxide-semiconductor (NMOS) transistor; and
a drain and source of the NMOS transistor of the first inverter are connected to a source and drain of the PMOS transistor of the second inverter, respectively.

4. The interface device of claim 1, further comprising an inverter configured to invert a phase of the applied digital baseband signal by 180 degrees and to output the inverted signal.

5. The interface device of claim 1, further comprising a device connected to an input terminal and configured to eliminate a direct current (DC) component from the digital baseband signal input to the input terminal.

6. The interface device of claim 5, wherein the device configured to eliminate the DC component is a capacitor.

7. The interface device of claim 1, wherein the first and second inverters, when the digital baseband signal is “0,” output signals having a value of VDD and a value of VSS, respectively, and, when the digital baseband signal is “1,” output signals having identical values.

8. A transmitter, comprising:
a first signal processing unit configured to, when a first digital baseband signal is input, output a first signal based on the first digital baseband signal, and output a second signal based on a signal obtained by inverting a phase of the first digital baseband signal;
a second signal processing unit configured to, when a second digital baseband signal is input, convert the second digital baseband signal into an analog signal, eliminate a high frequency component from the analog signal, and output a signal free of the high frequency component; and
a frequency mixing unit configured to modulate and output an output signal of the first or second signal processing unit.

9. The transmitter of claim 8, wherein the first signal processing unit, when the digital baseband signal is “0,” outputs the first and second signals having different values, and, when the digital baseband signal is “1,” outputs the first and second signals having identical values.

10. The transmitter of claim 8, wherein the first digital baseband signal is a digital baseband signal for on-off keying (OOK) modulation.

11. The transmitter of claim 8, wherein the second digital baseband signal is a digital baseband signal for phase-shift keying (PSK) modulation or quadrature amplitude modulation (QAM).

12. The transmitter of claim 8, further comprising:
a power amplification unit configured to amplify an output signal of the frequency mixing unit; and
an antenna configured to propagate the amplified output signal.
